(19) United States
(12) Patent Application Publication
(10) Pub. No.: US 2021/0151632 A1
(43) Pub. Date: May 20, 2021

(54) Optoelectronic Device Comprising a Passivation Layer and Method of Manufacturing the Optoelectronic Device

(71) Applicant: OSRAM OLED GMBH, Regensburg (DE)

(72) Inventors: David O'BRIEN, Portland, OR (US); Ivar TANGRING, Regensburg (DE); Vesna MUELLER, Vaterstetten (DE)

(73) Assignee: OSRAM OLED GmbH, Regensburg (DE)

(21) Appl. No.: 17/045,102

(22) PCT Filed: Apr. 10, 2019
(86) PCT No.: PCT/EP2019/059082

§ 371 Date: Oct. 2, 2020

(30) Foreign Application Priority Data
Apr. 13, 2018 (DE) 10 2018 108 875.2

(51) Int. Cl. H01L 33/44; H01L 33/50

(52) U.S. Cl. CPC H01L 33/44; H01L 33/502; H01L 2933/0091; H01L 2933/0041; H01L 2933/0025

(57) ABSTRACT

An optoelectronic device including a passivation layer and a method for manufacturing an optoelectronic device are disclosed. In an embodiment an optoelectronic device includes an optoelectronic semiconductor chip comprising optoelectronic semiconductor layers configured to generate electromagnetic radiation, the optoelectronic semiconductor layers having a first semiconductor layer from which the generated electromagnetic radiation is configured to be coupled out and a passivation layer in direct contact with a first main surface of the first semiconductor layer, wherein the passivation layer includes quantum dot particles configured to convert a wavelength of the electromagnetic radiation, wherein the passivation layer has a refractive index larger than 1.6, and wherein a surface of the passivation layer remote from the first semiconductor layer forms a first main surface of the optoelectronic device.

This patent application is a national phase filing under section 371 of PCT/EP2019/059082, filed Apr. 10, 2019, which claims the priority of German patent application 10 2018 108 875.2, filed Apr. 13, 2018, each of which is incorporated herein by reference in its entirety.

### TECHNICAL FIELD

A light emitting diode (LED) is a light-emitting device that is based on semiconductor materials. Generally, an LED comprises a pn-junction. When electrons and holes recombine with each other in the region of the pn-junction, for example, since a corresponding voltage is applied, electromagnetic radiation is generated. LEDs have been developed for a variety of applications comprising display devices, illumination devices, automotive lighting, projectors and others. For example, arrays of LEDs or light-emitting portions, each comprising a plurality of LEDs or light-emitting portions have been broadly employed for these purposes.

### SUMMARY

Embodiments provide an improved optoelectronic device as well as an improved method of manufacturing an optoelectronic device.

According to embodiments, an optoelectronic device comprises an optoelectronic semiconductor chip comprising optoelectronic semiconductor layers that are configured to generate electromagnetic radiation. The optoelectronic semiconductor layers comprise a first semiconductor layer, from which the electromagnetic radiation generated is configured to be coupled out. The optoelectronic device further comprises a passivation layer in direct contact with a first main surface of the first semiconductor layer. The passivation layer includes quantum dot particles that are configured to convert a wavelength of the electromagnetic radiation generated.

The passivation layer has, for example, a layer thickness less than 10 μm, for example, less than 5 μm and further less than 3 μm or less than 1 μm.

The quantum dot particles may, for example, comprise CdSe, CdS, InP or ZnS.

According to embodiments, the passivation layer may further comprise passive quantum dot particles. The passive quantum dot particles may, for example, not be configured or to a small extent configured to convert the wavelength of the generated electromagnetic radiation. By way of example, an absorption wavelength of the passive quantum dot particles may be smaller than a wavelength of the electromagnetic radiation generated.

The passivation layer may comprise silicon oxide, titanium oxide, aluminum oxide, zirconium oxide, silicon nitride or mixtures of these materials. According to further embodiments, the passivation layer may comprise further particles that are suitable for increasing a refractive index of the passivation layer. For example, the passivation layer may have a refractive index larger than 1.6.

According to embodiments, the optoelectronic device may comprise a first region and a second region, wherein a layer thickness of the passivation layer in the first region differs from the layer thickness of the passivation layer in the second region.

According to further embodiments, the passivation layer may comprise a first portion and a second portion, wherein the first portion of the passivation layer has a composition different from the composition of the second portion of the passivation layer.

By way of example, a first main surface of the passivation layer may form a first main surface of the optoelectronic device.

According to embodiments, the first main surface of the passivation layer may be roughened.

According to embodiments, a method of manufacturing an optoelectronic device comprises applying a passivation layer in direct contact with a first main surface of a first semiconductor layer of an optoelectronic semiconductor chip comprising optoelectronic semiconductor layers that are configured to generate electromagnetic radiation. The optoelectronic semiconductor layers comprise the first semiconductor layer, from which the electromagnetic radiation generated is configured to be coupled out. The passivation layer comprises quantum dot particles that are configured to convert a wavelength of the electromagnetic radiation generated.

By way of example, the passivation layer may be formed by a sol-gel process.

The method may further comprise locally thinning the passivation layer so that the optoelectronic device comprises a first region and a second region, wherein a layer thickness of the passivation layer in the first region differs from the layer thickness of the passivation layer in the second region.

For example, a first portion and a second portion of the passivation layer may each be applied in a patterned manner so that the passivation layer comprises a first portion and a second portion. The first portion of the passivation layer has a composition different from the composition of the second portion of the passivation layer.

The method may further comprise roughening a first main surface of the passivation layer.

### BRIEF DESCRIPTION OF THE DRAWINGS

The accompanying drawings serve to provide a further understanding of embodiments. The drawings illustrate the embodiments o and together with the description serve to explain the principles. Other embodiments and many of the intended advantages will be readily appreciated from the following detailed description. The elements of the drawings are not necessarily to scale relative to each other. Like reference numbers designate corresponding similar parts and structures.

FIG. 1 shows a schematic cross-sectional view of a part of an optoelectronic device;

FIG. 2 shows a cross-sectional view of a part of an optoelectronic device to illustrate emission processes;

FIG. 3 shows a cross-sectional view of an optoelectronic device in accordance with further embodiments;

FIG. 4A shows a further cross-sectional view of an optoelectronic device in accordance with embodiments; and

FIG. 4B shows a schematic plan view of a portion of an optoelectronic device.

### DETAILED DESCRIPTION OF ILLUSTRATIVE EMBODIMENTS

In the following detailed description reference is made to the accompanying drawings, which form a part hereof and which are illustrated by way of illustration specific embodiments. In this context, directional terminology such as “top”, “bottom”, “front”, “back”, “over”, “on”, “above”, “leading”, “trailing” etc. is used with reference to the orientation of the Figures being described. Since components of embodiments can be positioned in a number of different orientations, the directional terminology is used for purposes of illustration and is in no way limiting.

The description of the embodiments is not limiting since other embodiments may be utilized and structural or logical changes may be made without departing from the scope defined by the claims. In particular, elements of the embodiments described hereinafter may be combined with elements of different embodiments, unless the context indicates otherwise.

The terms “wafer” or “semiconductor substrate” used in the following description may include any semiconductor-based structure that has a semiconductor surface. Wafer and structure are to be understood to include doped and undoped semiconductors, epitaxial semiconductor layers, e.g., supported by a base semiconductor foundation, and other semiconductor structures. For example, a layer of a first semiconductor material may be grown on a growth substrate made of a second semiconductor material or made of an insulating material such as a sapphire substrate. Depending on an intended use, the semiconductor may be based on a direct or an indirect semiconductor material. Examples of semiconductor materials particularly suitable for generation of electromagnetic radiation comprise nitride-compound semiconductors, by which e.g., ultraviolet or blue light or longer wavelength light may be generated, such as GaN, InGaN, AlN, AlGaN, AlGaInN, phosphide-compound semiconductors, by which e.g., green or longer wavelength light may be generated such as GaAsP, AlGaInP, GaP, AlGaP, as well as further semiconductor materials including AlGaAs, SiC, ZnSe, GaAs, ZnO, Ga₂O₃, diamond, hexagonal BN und combinations of these materials. The stoichiometric ratio of the ternary or quaternary compounds may vary. Further examples of semiconductor materials may as well be silicon, silicon-germanium and germanium. In the context of the present specification, the term “semiconductor” further encompasses organic semiconductor materials.

The terms “lateral” and “horizontal” as used in this specification intend to describe an orientation which runs essentially parallel to a first surface of a substrate or semiconductor body. This can be for instance the surface of a wafer or a die or a chip.

The term “vertical” as used in this specification intends to describe an orientation which is essentially perpendicular to the first surface of a substrate or semiconductor body.

As used herein, the terms “having”, “containing”, “including”, “comprising” and the like are open ended terms that indicate the presence of stated elements or features, but do not preclude additional elements or features. The indefinite and definite articles include both the plural and the singular, unless the context clearly indicates otherwise.

As employed in this specification, the term “electrically connected” intends to describe a low-ohmic electric connection between the elements electrically connected together. The electrically connected elements need not essentially be directly connected. Intervening elements may be provided between the electrically connected elements.

The term “electrically connected” further comprises tunneling contacts between connected elements.

Generally, the wavelength of electromagnetic radiation emitted by an LED chip may be converted using a converter material that comprises a phosphor. For example, white light may be generated by a combination of an LED chip emitting blue light with a suitable phosphor. For example, the phosphor may be a yellow phosphor which is configured to emit yellow light when being excited by the light of the blue LED chip. The phosphor may, for example, absorb a portion of the electromagnetic radiation emitted by the LED chip. The combination of blue and yellow light is perceived as white light. By adding further phosphors that are configured to emit light of a further wavelength, e.g., red, for example, the color temperature, the color quality, the luminous efficiency or further properties of the generated light may be changed. According to further concepts, white light may be generated by a combination that comprises a blue LED chip and a green as well as a red phosphor. As is to be understood, a converter material may comprise several different phosphors, each of which emitting different wavelengths.

According to embodiments, a phosphor material, e.g., a phosphor powder is embedded in a suitable matrix material. A suitable matrix material may be—within the scope of the present specification—a passivation layer that is provided for encapsulating the light-emitting chip, as will be explained in the following description. In particular, the particles of the phosphor may be quantum dot particles. To be more specific, the phosphor material may be in the form of nanoparticles or microcrystals that are implemented as quantum dots.

Quantum dots (“QDs” also referred to as semiconductor nanocrystals) are small crystals made of II-VI-, III-V-, IV-V-materials, which typically have a diameter of 1 nm to 20 nm, corresponding to the range of the de-Broglie wavelength of the charge carriers. The energy difference of the charge carrier states of a quantum dot is a function of the composition as well as of the physical size of the quantum dots. In other words, with a given material, by varying the size the emission spectrum of the quantum dots may be varied. As a consequence, by using quantum dots, a large range of wavelengths may be generated.

Usually, the quantum dots may comprise a core material that is surrounded by a coating material. The band gap of the semiconductor core material may be smaller than the band gap of the semiconductor coating material. For example, the core may be made up of CdSe and the coating may comprise CdS as well as optionally further layers. According to further embodiments, the core may be composed of InP and the coating includes ZnS and, optionally, further layers. Powders made from these quantum dots nanoparticles are commercially available. Basically, quantum dots may comprise one or more of the following materials: CdS, CdSe, CdTe, CdPo, ZnS, ZnSe, ZnTe, ZnPo, HgS, HgSe, HgTe, MgS, MgSe, MgTe, PbSe, PbS, PbTe, GaN, GaP, GaAs, InP, InAs, CuInS₂, CdS₁₋ₓSe, BaTiO₃, PbZrO₃, PbZrxTi₁₋ₓO₃, BaₓSr₁₋ₓ, SrTiO₃, LaMnO₃, CaMnO₃ und La₁₋ₓCaₓMnO₃.

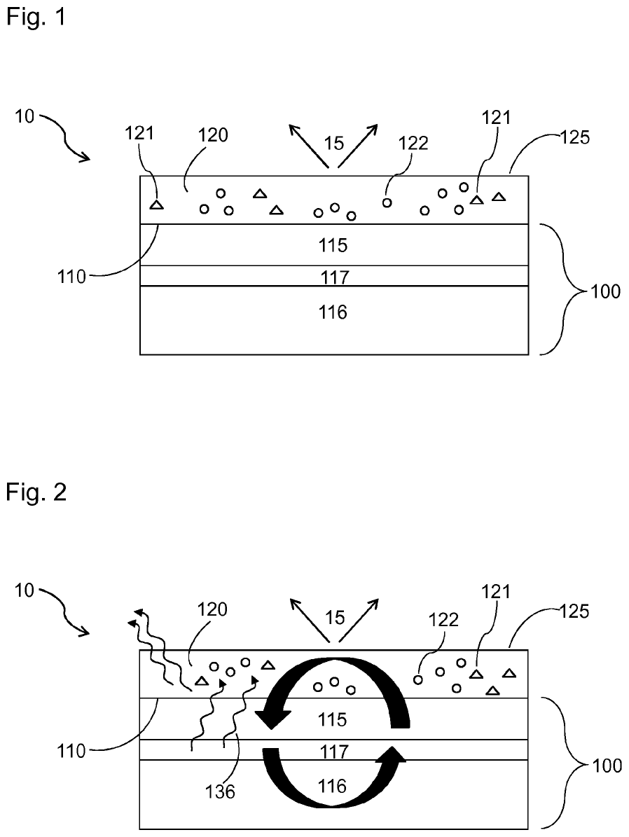

FIG. 1 shows a cross-sectional view of a part of the optoelectronic device 10 according to embodiments. The optoelectronic device 10 comprises an optoelectronic semiconductor chip 100 comprising optoelectronic semiconductor layers 115, 116, 117 that are configured to generate electromagnetic radiation. The optoelectronic semiconductor layers comprise a first semiconductor layer 115 from which the electromagnetic radiation 15 generated is configured to be coupled out. A passivation layer 120 is arranged in direct contact with the first main surface 110 of the first semiconductor layer 115. The passivation layer 120 includes quantum dot particles 121 that are configured to convert a wavelength of the electromagnetic radiation 15 generated.

The passivation layer 120 is arranged in contact with the semiconductor layer 115 from which the electromagnetic radiation 15 generated is coupled out. The passivation layer may, for example, comprise silicon dioxide. The passivation layer passivates the semiconductor layers of the optoelectronic semiconductor chip electrically and chemically and encapsulates them. In particular, a surface of the semiconductor layer is passivated by to this layer. Further, the semiconductor layer is protected from environmental influences both mechanically and chemically and electrically. A first main surface 125 of the passivation layer 120 forms the first main surface of the optoelectronic device 10.

According to embodiments this passivation layer 120 includes quantum dots particles 121. These quantum dot particles 121 serve as a converter material for converting the electromagnetic radiation emitted by the optoelectronic device. For example, the quantum dots may be nanoparticles typically comprising CdSe, CdS, InP or ZnS having a high refractive index. Due to the fact that the passivation layer 120 comprises these quantum-dot particles 121, additionally, the refractive index of the passivation layer 120 is increased.

As a result, depending on the concentration of the quantum dot particles 121, the refractive index of the passivation layer 120 may be increased and may be matched to the refractive index of the semiconductor layers of the semiconductor chip 100. As a result, it is possible to reduce a difference between the refractive index of the first semiconductor layer and the passivation layer as compared with a commonly employed passivation layer having no quantum dot particles. As a consequence, the outcoupling efficiency of the optoelectronic device may be increased. For example, the refractive index of the passivation layer comprising quantum dot particles 121 may be larger than 1.6 or 1.8, for example, even larger than 2.0.

According to further embodiments, the passivation layer 120 may further comprise passive quantum dot particles 122. In the context of the present specification, passive quantum dot particles 122 are those quantum dot particles which are not or only to a small extent or to a negligible extent configured to convert the wavelength of the electromagnetic radiation generated. For example, the passive quantum dot particles 122 may be configured to absorb light having a smaller wavelength than the electromagnetic radiation emitted by the optoelectronic semiconductor chip. Such passive quantum dot particles 122 may be added in order to further increase the refractive index of the passivation layer 120. For example, the refractive index of the passivation 120 comprising converting quantum dot particles 121 and passive quantum dot particles 122 may be larger than 2.0 or 2.1.

The passivation layer may, for example, comprise or may be composed of transparent inorganic compounds such as inorganic oxides including silicon dioxide, metallic oxides such as titanium dioxide, aluminum oxide or zirconium oxide, or silicon nitride or mixtures of these compounds. For example, the passivation layer may be implemented as a sol-gel layer and may comprise any of the above-mentioned materials. Further examples comprise polymers such as silicone or acrylate, for example, polymethyl methacrylate (PMMA).

The optoelectronic semiconductor chip 100 may, for example, comprise a first semiconductor layer 115, for example, of a first conductivity type, for example, n-type as well as a second semiconductor layer 116 of a second conductivity type, for example, p-type. An active layer 117, for example, a layer comprising one or more quantum wells may be arranged between the first semiconductor layer 115 and the second semiconductor layer 116. The material of the first and the second semiconductor layers 115, 116 may, for example, be a III/V-semiconductor material. Examples comprise in particular nitride compound semiconductors or phosphide compound semiconductors as has been described above.

As is illustrated in FIG. 1, the passivation layer 120 comprising the quantum dot particles 121 is formed directly adjacent to the first main surface 110 of the first semiconductor layer 115. In a corresponding manner, electromagnetic radiation emitted by the optoelectronic semiconductor chip 100 is directly converted in the passivation layer 120. As a result, it is possible to provide a compact and efficient optoelectronic semiconductor device. Since the quantum dot particles have a smaller diameter than generally employed bulk phosphors that are not based on quantum effects, a converter-containing optoelectronic device having a particularly compact size may be provided. Since the passivation layer, which comprises quantum dot particles, has an increased refractive index, the outcoupling efficiency of the optoelectronic semiconductor device may be increased.

FIG. 2 shows a schematic cross-sectional view of the semiconductor device shown in FIG. 1 for illustrating the emission process. In addition, photons 136 that are, for example, emitted by the active layer 117 are shown. These are converted by the quantum dot particles 121 included in the passivation layer 120. Due to the difference of the refractive index between air and the passivation layer 120, at the interface, i.e. the first main surface 125 of the optoelectronic device reflection of a certain portion of the emitted radiation takes place. In other words, the emitted electromagnetic radiation is reflected back to the semiconductor chip 100, and from this in turn is reflected in the direction of the passivation layer 120. To be more specific, the light is reflected within the chip between the first main surface 125 and the back of the device until it has the suitable exit angle due to scattering at particles and is finally coupled out. As a result, the probability that a single photon will be converted in its wavelength by a quantum dot particle 121 is significantly larger than in devices, in which such a reflection does not take place. Due to the fact that the quantum dot particles 121 are arranged in the passivation layer 120 itself, a sufficiently high proportion of the emitted electromagnetic radiation may be converted as a result of this reflection behavior. The reflection at the interface, which is disadvantageous in conventional optoelectronic devices, is thus utilized to increase the proportion of converted radiation.

Due to the fact that the light is converted within the passivation layer, the outcoupling efficiency of the emitted light is increased. Due to the fact that the semiconductor chip and converter are in a close spatial relationship and are compactly integrated, the coupling of the electromagnetic radiation emitted by the semiconductor chip to the converter is greatly improved. Due to the short thermal path to the chip, heat generated in the converter material may be efficiently dissipated via the semiconductor chip. Since the thermal path length now is smaller than 1 μm, the thermal conductivity of the conversion matrix material is not decisive for the heat dissipation. Since the converter material is integrated directly in the passivation layer, the manufacture of the semiconductor device is largely simplified. It is not necessary to provide a separate converter element.

For example, the quantum dot particles 121 have a size of approximately 10 nm. The layer thickness of the passivation layer is a few 100 nm. For example, in the case of complete conversion the layer thickness may be 1 to 2 μm. The layer thickness may even be smaller than 1 μm. It is possible that if the layer thickness is smaller than 1 μm no complete conversion takes place. Overall, the layer thickness of the passivation layer comprising a converter may be smaller than 3 μm. For example, apart from the quantum dot particles 121, the passivation layer does not comprise any further bulk phosphor or phosphor that is not based on quantum effects. Phosphors conventionally used have a diameter greater than 1 μm. If the passivation layer does not comprise additional phosphor, the layer thickness of the passivation layer 120 comprising a converter material may also be reduced compared to the layer thicknesses of conventional converters. According to further embodiments, the surface 225 of the passivation layer 120 may be roughened. In addition, scattering particles or optical defects may be incorporated in order to increase the outcoupling rate of the generated electromagnetic radiation.

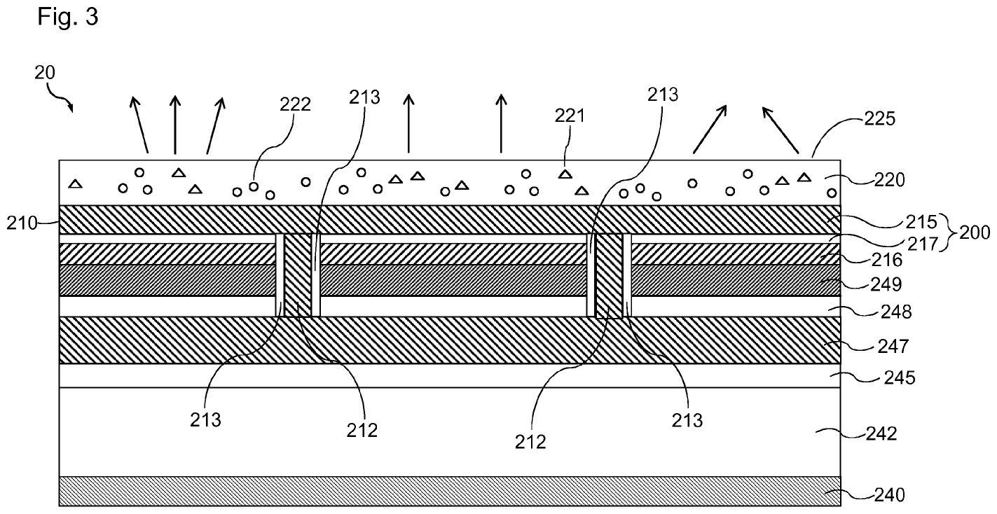

FIG. 3 shows a cross-sectional view of a part of the optoelectronic device according to further embodiments. For example, the shown device is based on “thin GaN semiconductor devices”. After growing semiconductor layers for generating electromagnetic radiation on a growth substrate these are arranged on a carrier that is different from the growth substrate. For example, a suitable carrier 242 may be applied over an epitaxially grown semiconductor layer stack. Subsequently, the growth substrate is removed.

The optoelectronic device shown in FIG. 3 comprises a carrier 242, for example, made of an insulating material that is different from the growth substrate. A back side metallization 240 made of an electrically conductive material is provided on one side of the carrier 242. A bonding material 245 for bonding the semiconductor chip 200 to the carrier 242 is applied to a side of the carrier 242 remote from the back side metallization layer 240. A first current spreading layer 247 is arranged over the bonding material 245. The first current spreading layer 247 is provided for electrically contacting the first semiconductor layer 215 and may, for example, comprise a metallic material. The first current spreading layer 247 is insulated from a second current spreading layer 249 by means of an insulating material 248. The second current spreading layer 249 is electrically connected with a second semiconductor layer 216. The second current spreading layer 249 may comprise a metallic material. For example, the layer 216 may be a semiconductor layer of a second conductivity type, for example, p-type. The first semiconductor layer 215 may be a semiconductor layer of a first conductivity type, for example, n-type. An active layer 207 as has been described above, may be arranged between the first and the second semiconductor layers 215, 216.

For example, the respective semiconductor layers may be based on a III-V-semiconductor system such as a nitride semiconductor system or a phosphide semiconductor system or a nitride-phosphide semiconductor system. The first semiconductor layer 215 is electrically connected with the first current spreading layer 247 by means of contact elements 212. The contact elements 212 may be insulated from adjacent layers by means of an insulating material 213. For example, the contact elements 212 may be formed in a columnar manner or as posts and may extend at regular intervals, for example.

A passivation layer 220 that comprises, as has been described above, converting quantum dot particles 221 is arranged over the first main surface 210, over which the electromagnetic radiation generated by the semiconductor chip 200 is emitted and contacts the first main surface 21. Due to the fact that the converter is formed in direct contact with the semiconductor layer 100, an optoelectronic device 20 having a compact size may be implemented. According to embodiments, the passivation layer 220 may further comprise passive quantum dot particles 222.

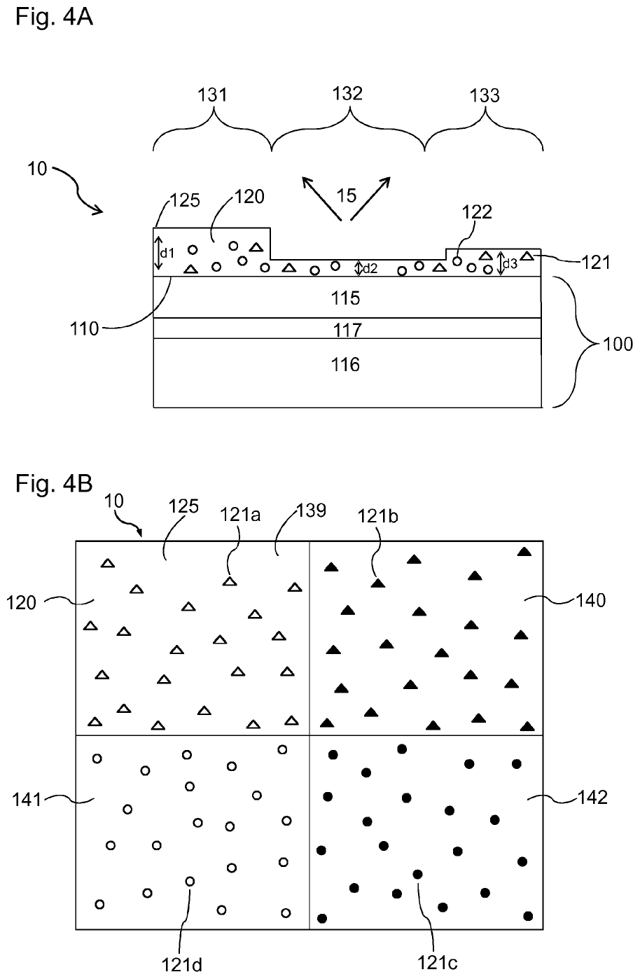

FIG. 4A shows a cross-section of a part of a semiconductor device according to further embodiments. As is shown, the optoelectronic semiconductor device 10 comprises a first region 131, a second region 132 and a third region 133. In the first region 131, the passivation layer 120 has a first layer thickness d1. In the second region, the passivation layer 120 has a layer thickness d2. In the third region 133, the passivation layer 120 has a layer thickness d3. The passivation layer 120 comprises converting quantum dot particles 121 and, optionally, passive quantum dot particles 122. As a result, electromagnetic radiation 15 emitted from the semiconductor chip 100 is converted to a different extent in the different regions 131, 132, 133. For example, the electromagnetic radiation emitted from the first region 131 is converted to a larger extent than the electromagnetic radiation emitted from the second region 132. In a corresponding manner, by patterning the passivation layer 120 in which the passivation layer 120 is selectively thinned, an optoelectronic device may be provided that emits different electromagnetic radiation from different regions of the surface.

FIG. 4B shows a plan view of a further optoelectronic semiconductor device 10. The passivation layer 120 comprises a first portion 139, a second portion 140, a third portion 141 and a fourth portion 142. The different portions each have a different composition. For example, the different portions each comprise different quantum dot particles 121a, 121b, 121c, 121d. To be more specific, the different portions comprise quantum dot particles converting the radiated light to different wavelengths, respectively. For example, by the patterned application of the respective different passivation layer, for example, each comprising different converter materials, it is possible to provide an optoelectronic semiconductor device 10 that emits different wavelength from different regions of the surface.

According to further embodiments, the term “different composition” may as well mean that the concentration of the quantum dot particles in the respective portions is different, respectively. According to a further embodiment the matrix material of the passivation layer 120, 220 may be different. For example, the first portion of the passivation layer may comprise silicon oxide, and the second portion of the passivation layer includes a different material or silicon oxide comprising further additives. Thereby, for example, the refractive index may vary locally whereby the properties of the optoelectronic device may be locally changed.

When patterning the passivation layer, for example, chips comprising different emission portions or pixels may be generated. Due to the small size of the quantum dot particles in comparison to conventional bulk phosphors, even very small pixel sizes may be very large in comparison to the single converter particles. This enables smaller pixels having a more homogeneous color distribution to be achieved. Due to the close contact between the light-emitting semiconductor chip and the converter cross-talking with neighboring pixels may be avoided.

A method of manufacturing an optoelectronic device 10, 20 comprises forming an optoelectronic semiconductor chip 100, 200 comprising optoelectronic semiconductor layers that are configured to generate electromagnetic radiation, wherein the optoelectronic semiconductor layers comprise a first semiconductor layer 115, 215 from which the generated electromagnetic radiation 15 is configured to coupled out. Then, a passivation layer 120, 220 is formed in direct contact with a first main surface 110, 210 of the first semiconductor layer 115, 215, wherein the passivation layer 120, 220 includes quantum dot particles 121, 221 that are configured to convert a wavelength of the electromagnetic radiation 15 generated. The passivation layer 120, 220 may be formed in direct contact with the first main surface 110, 210 of the first semiconductor layer 115, 215.

For example, the passivation layer 120, 220 may be manufactured using a PECVD method (“Plasma Enhanced Chemical Vapor Deposition”) using TEOS (tetraethyl orthosilicate) as a starting material. According to further embodiments, the passivation layer 120, 220 may be deposited from the gas phase by an alternative method. In the case of deposition from the gas phase, a quantum dot particle containing material, for example, a suitable fluid may be added to the starting materials. According to further embodiments the passivation layer may be formed by sputtering.

According to further embodiments the passivation layer may be formed by a so-called sol-gel process for example, by spinning or printing a suitable coating solution. For example, the quantum dots may be added as a nanoparticle powder to the fluid or the coating solution used in the sol-gel process. Basically, when using the sol-gel process, every sol-gel matrix that becomes a stable passive layer after heat treatment and conversion into an oxide may be used for manufacturing the passivation layer. For example, a sol-gel matrix that becomes an oxide having a higher refractive index may be used. Examples for suitable oxides comprise particularly transparent oxides such as SiO₂, as well as metallic oxides such as TiO₂, Al₂O₃ or ZrO₂. According to further embodiments, for example, oxides such as TiO₂, Al₂O₃ or ZrO may be further added to the passivation layer in order to increase the refractive index.

Although specific embodiments have been illustrated and described herein, those skilled in the art will recognize that the specific embodiments shown and described can be replaced by a variety of alternative and/or equivalent configurations without departing from the scope of the invention. The application is intended to cover any adaptations or variations of the specific embodiments discussed herein. Therefore, the invention is to be limited only by the claims and their equivalents.

1-18. (canceled)

19. An optoelectronic device comprising:
an optoelectronic semiconductor chip comprising optoelectronic semiconductor layers configured to generate electromagnetic radiation, the optoelectronic semiconductor layers comprising a first semiconductor layer from which the generated electromagnetic radiation is configured to be coupled out; and
a passivation layer in direct contact with a first main surface of the first semiconductor layer,
wherein the passivation layer includes quantum dot particles configured to convert a wavelength of the electromagnetic radiation,
wherein the passivation layer has a refractive index larger than 1.6, and
wherein a surface of the passivation layer remote from the first semiconductor layer forms a first main surface of the optoelectronic device.

20. The optoelectronic device according to claim 19, wherein the optoelectronic device comprises a first region and a second region, and wherein a layer thickness of the passivation layer in the first region is different from a layer thickness of the passivation layer in the second region.

21. The optoelectronic device according to claim 19, wherein the passivation layer has a layer thickness smaller than 10 μm.

22. The optoelectronic device according to claim 19, wherein the quantum dot particles comprise CdSe, CdS, InP or ZnS.

23. The optoelectronic device according to claim 19, wherein the passivation layer further comprises passive quantum dot particles that are not configured to convert the wavelength of the electromagnetic radiation.

24. The optoelectronic device according to claim 19, wherein the passivation layer comprises silicon dioxide, titanium dioxide, aluminum oxide, zirconium oxide or silicon nitride.

25. The optoelectronic device according to claim 19, wherein the passivation layer comprises further particles that are configured to increase the refractive index of the passivation layer.

26. The optoelectronic device according to claim 19, wherein the passivation layer comprises a first portion and a second portion, and wherein a composition of the first portion of the passivation layer differs from a composition of the second portion of the passivation layer.

27. The optoelectronic device according to claim 19, wherein the first main surface of the passivation layer is roughened.

28. The optoelectronic device according to claim 19, wherein the refractive index of the passivation layer is larger than 2.0.

29. A method for manufacturing an optoelectronic device, the method comprising:
applying a passivation layer in direct contact with a first main surface of a first semiconductor layer of an optoelectronic semiconductor chip comprising optoelectronic semiconductor layers configured to generate electromagnetic radiation,
wherein the optoelectronic semiconductor layer comprises the first semiconductor layer from which the electromagnetic radiation is configured to be coupled out,
wherein the passivation layer includes quantum dot particles configured to convert a wavelength of the electromagnetic radiation,
wherein the passivation layer has a refractive index larger than 1.6, and
wherein a surface of the passivation layer remote from the first semiconductor layer forms a first main surface of the optoelectronic device.

30. The method according to claim 29, further comprising locally thinning the passivation layer so that the optoelectronic device comprises a first region and a second region, wherein a layer thickness of the passivation layer in the first region is different from the layer thickness of the passivation layer in the second region.

31. The method according to claim 29, wherein the passivation layer has a layer thickness smaller than 10 μm.

32. The method according to claim 29, wherein the passivation layer is applied by a sol-gel process.

33. The method according to claim 29, wherein a first portion and a second portion of the passivation layer are each applied in a patterned manner so that the passivation layer comprises the first portion and the second portion, and wherein a composition of the first portion of the passivation layer differs from a composition of the second portion of the passivation layer.

34. The method according to claim 29, further comprising roughening the first main surface of the passivation layer.

35. The method according to claim 29, wherein the refractive index of the passivation layer is larger than 2.0.
